(19) United States
(12) Patent Application Publication
(10) Pub. No.: US 2015/0303169 A1
(43) Pub. Date: Oct. 22, 2015

(54) SYSTEMS AND METHODS FOR MULTIPLE BALL BOND STRUCTURES

(71) Applicants: Tu-Anh N. Tran, Austin, TX (US); Yin Kheng Au, Petaling Jaya (MY); Burton J. Carpenter, Austin, TX (US); Chu-Chung Lee, Round Rock, TX (US)

(72) Inventors: Tu-Anh N. Tran, Austin, TX (US); Yin Kheng Au, Petaling Jaya (MY); Burton J. Carpenter, Austin, TX (US); Chu-Chung Lee, Round Rock, TX (US)

(21) Appl. No.: 14/255,450

(22) Filed: Apr. 17, 2014

(51) Int. Cl. H01L 23/00

(52) U.S. Cl. CPC H01L 24/85; H01L 24/46; H01L 2224/48453; H01L 2224/85801

(57) ABSTRACT

A method for forming a semiconductor device includes forming a first ball bond on a first contact pad, in which the first ball bond has a first wire segment of a bonding wire extending from the ball bond; forming a mid-span ball in the first wire segment at a first distance from the ball bond; and after the forming the mid-span ball, attaching the mid-span ball to a second contact pad to form a second ball bond.

### BACKGROUND

1. Field

This disclosure relates generally to wire bonding, and more specifically, to systems and methods for multiple ball bond structures.

2. Related Art

In semiconductor manufacturing processes, certain bonding surfaces may be composed partially or entirely of certain metals in order to improve a wire bonding process. The metal composition may be one of the primary drivers in choosing the particular type of wire bonding process chosen.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates an example semiconductor structure implementing multiple ball bond structures, in accordance with certain embodiments of the present disclosure;

FIG. 2 illustrates an example semiconductor structure implementing two ball bonds formed from a single wire, and terminated at stitch bond, in accordance with certain embodiment of the present disclosure;

FIG. 3 illustrates a second example semiconductor structure implementing two ball bonds formed from a single wire, and terminated at terminal ball, in accordance with certain embodiment of the present disclosure;

FIG. 4 illustrates an example first ball formation, in accordance with certain embodiments of the present disclosure;

FIG. 5 illustrates a cross-section of an example deformation of first ball during formation of first ball bond, in accordance with certain embodiments of the present disclosure;

FIG. 6 illustrates a cross-section of an example second ball formation, in accordance with certain embodiments of the present disclosure;

FIG. 7 illustrates a cross-section of an example deformation of second ball 604 during formation of second ball bond, in accordance with certain embodiments of the present disclosure; and

FIG. 8 illustrates a cross-section of an example pre-formation, in accordance with certain embodiments of the present disclosure.

### DETAILED DESCRIPTION

When coupling multiple portions of a semiconductor structure (or coupling multiple semiconductor structures to one another) via wire, one or more wire bonding processes may be implemented. Different wire bonding processes may result in bonds with different physical and/or mechanical properties. For example, a ball bond may have greater tolerance to certain types of mechanical stresses than a stitch bond.

For example, a ball bond process may be implemented to couple a chip to a package substrate. The ball bond process may include two portions: a first bond in which a wire is bonded via a ball bond to a first bonding surface, and a termination point at which the wire is terminated. The termination point may be a number of different termination types, including a stitch bond to a different bonding surface (or a different portion of the same bonding surface) and/or a terminal ball.

Depending on the semiconductor structure to which the wire is to be bonded, different materials may be deposited in order to effectuate the wire bond. For example, a ball grid array package substrate may include a portion plated with noble metals such as gold (and/or alloys of such metals). This plating layer may allow for better bonding properties than the underlying metal layers (e.g., the underlying copper layer(s)).

The wire bonding process chosen may depend on a variety of factors, including wire material (e.g., Copper, Aluminum, Silver, Gold, etc.), bonding surface material (e.g., Gold, Gold alloys, Silver, Silver alloys, etc.), bonding surface type (e.g., semiconductor substrate, package substrate, etc.), design considerations, etc. For example, when performing a ball bond process bonding a copper wire to an Aluminum die pad (e.g., a first bond in a ball bond process), an intermetallic connection may form between the gold and aluminum, with a ball bond being preferred for that particular connection. Using the same example, when terminating the copper wire at a nickel/gold pad on a package substrate (e.g., a second bond in a ball bond process), no intermetallic connection may form, and only a stitch bond may be sufficient.

However, bonding materials may be chosen in order to reduce the cost associated with forming a die, package substrate, wire, and/or other semiconductor structure or structures. For example, as the cost of gold increases, alternatives to nickel/gold substrate layers may be utilized. In such a circumstance, a stitch bond may be insufficient for a second bond in a ball bond process.

In the same or alternative configurations, it may be necessary or desirable to bond among multiple semiconductor structures using a single wire bonding path rather than multiple paths. Multiple paths may be necessary using traditional techniques in order to protect the structural integrity of the underlying semiconductor structure(s).

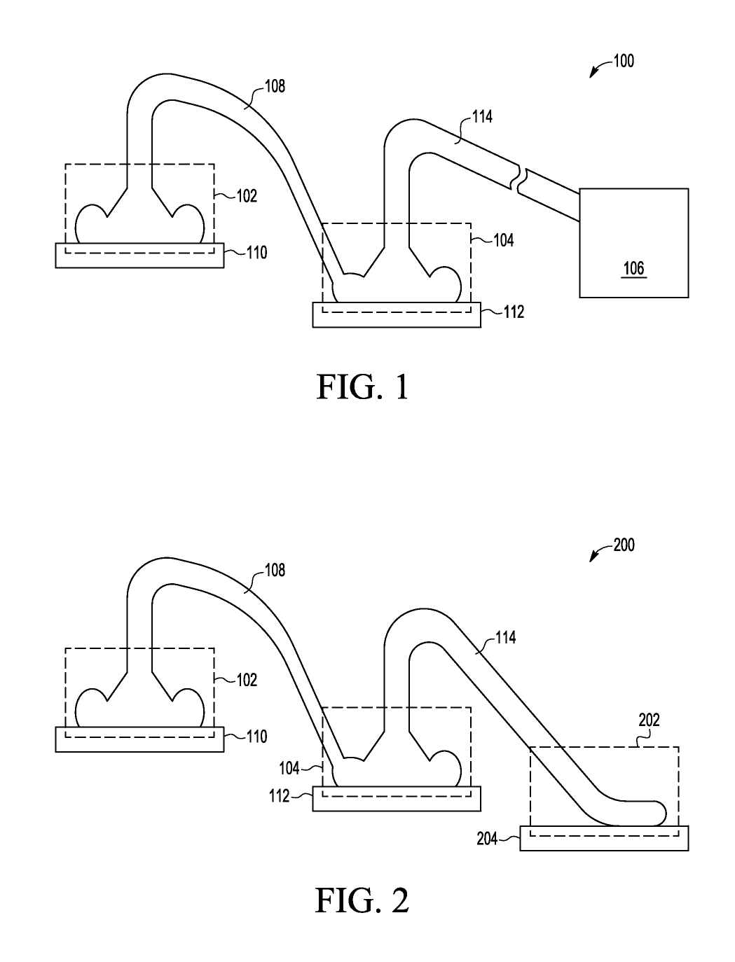

Disclosed are systems and methods for multiple ball bond structures. These systems and methods allow for the formation of multiple ball bonds using a single wire and/or a single bonding path. As described in more detail below with reference to FIGS. 1-8, a plurality of balls may be formed in a single wire, and a corresponding plurality of ball bonds formed from the plurality of balls.

The semiconductor described herein can be any semiconductor material or combinations of materials, such as gallium arsenide, silicon germanium, silicon-on-insulator (SOI), silicon, monocrystalline silicon, the like, and combinations of the above. The package substrate described here can be comprised of a copper or copper alloy leadframe, or ball grid array substrate made of epoxy, plastic, FR-4, FR5, a Bismaleimide-Triazine resin, a fiberglass reinforced epoxy laminate, polytetrafluorethylene, ceramic, polyimide, or other suitable material.

FIG. 1 illustrates an example semiconductor structure 100 implementing multiple ball bond structures, in accordance with certain embodiments of the present disclosure. Structure 100 may include first ball bond 102, second ball bond 104 coupled to first ball bond 102 via first wire segment 108, and termination point 106 coupled to second ball bond 104 via second wire segment 114. Although structure 100 illustrates only two ball bonds (e.g., first ball bond 102 and second ball bond 104) and two wire segments (e.g., first wire segment 108 and second wire segment 114), one of ordinary skill in the art may appreciate that any number of ball bonds may be formed between first ball bond 102 and termination point 106.

In some embodiments, first ball bond 102 may be a ball bond formed by known ball bonding processes in order to bond first wire segment 108 to bonding surface 110. For example, first ball bond 102 may be a wire bond formed by known ball bonding processes in order to bond a copper wire to an aluminum bonding pad.

First ball bond 102 may be coupled to second ball bond 104 by first wire segment 108. As described in more detail below with reference to FIGS. 2-8, second ball bond 104 may, in some embodiments, be formed by subjecting a second ball formed from the bonded wire to a wire bonding process in order to bond the wire to bonding surface 112. For example, second ball bond 104 may be a wire bond formed in order to bond a copper wire to an aluminum bonding pad.

In some configurations, bonding surface 112 may be a pad on a package substrate or a pad on a different semiconductor structure and/or a different part of the same semiconductor structure than bonding surface 110. For example, bonding surface 112 may be a different contact pad on the same die as bonding surface 110, a contact pad on a different die from bonding surface 110, and/or a contact pad on a package substrate associated with a die including bonding surface 110.

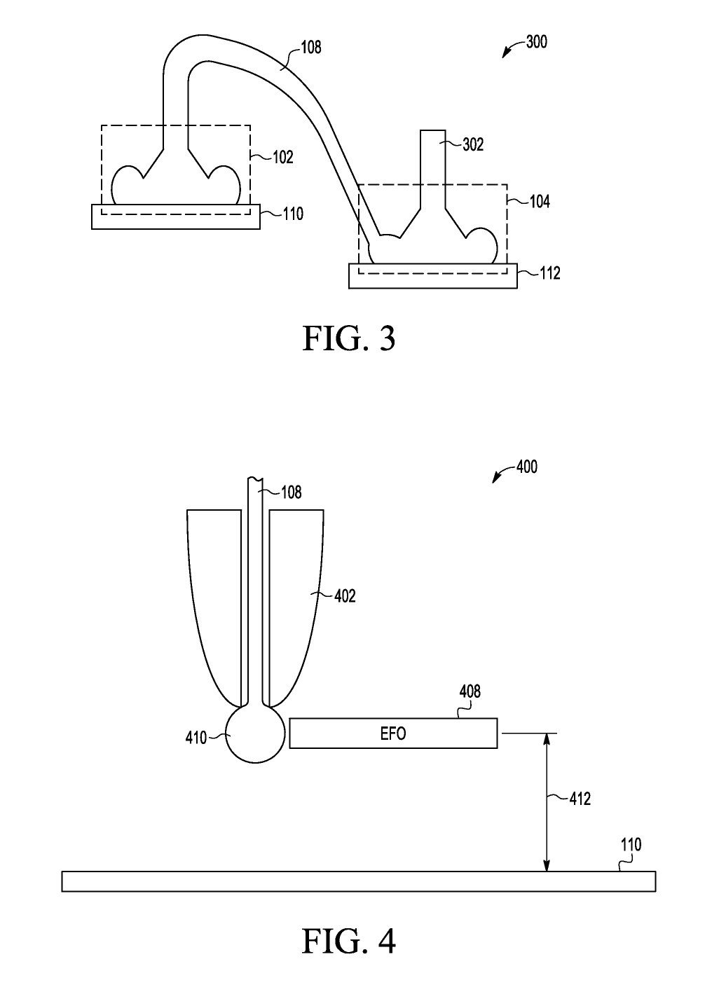

In some embodiments, second ball bond 104 may be coupled to termination point 106 via second wire segment 114. As mentioned previously, any number of additional ball bonds may be present between second ball bond 104 and termination 106. As described in more detail below with reference to FIGS. 2-3, termination point 106 may be any appropriate structure operable to terminate the wire including first and second wire portions 108, 114. For example, termination point 106 may be a stitch bond to a substrate (e.g., a stitch bond to a contact pad on the same substrate as bonding surface 112). As an additional example, termination point 106 may be a terminal ball formed from second wire portion 114.

FIG. 2 illustrates an example semiconductor structure 200 implementing two ball bonds 102, 104 formed from a single wire, and terminated at stitch bond 202, in accordance with certain embodiment of the present disclosure. In the example structure 200, second ball bond 104 and stitch bond 202 may be formed on the same substrate, and the substrate may be associated with a die including bonding surface 110.

In some embodiments, structure 200 may include stitch bond 202 bonded to bonding surface 204. Stitch bond 202, together with bonding surface 204 may generally correspond to termination point 106 as described in more detail above with reference to FIG. 1. For example, stitch bond 202 may be a stitch bond terminating a copper wire on a gold portion of a substrate.

In some embodiments, bonding surface 204 may be electrically coupled to bonding surface 112 such that bonding surfaces 112, 204 have substantially the same electrical potential. Although FIG. 2 illustrates one example of termination point 106, other configurations may be implemented without departing from the scope of the present disclosure.

FIG. 3 illustrates a second example semiconductor structure 300 implementing two ball bonds 102, 104 formed from a single wire, and terminated at terminal ball 302, in accordance with certain embodiment of the present disclosure. In the example structure 300, bonding surface 110 may be included in one semiconductor structure (e.g., a die) while bonding surface 112 may be included in a different portion of the same semiconductor structure and/or a different semiconductor structure than bonding surface 110 (e.g., a substrate associated with the die). Although FIG. 3 illustrates one example of termination point 106, other configurations may be implemented without departing from the scope of the present disclosure.

The plurality of ball bonds illustrated in FIGS. 1-3 may be formed by forming a plurality of corresponding balls in the same wire in order to form a single wire path including the plurality of ball bonds.

FIG. 4 illustrates an example first ball formation 400, in accordance with certain embodiments of the present disclosure. First ball formation 400 may include one or more pieces of equipment operable to bond first wire segment 108 to bonding surface 110. In some embodiments, first ball formation 400 may include forming first ball 410 from first wire segment 108. First ball 410 may be a segment of first wire portion 108 enlarged to facilitate a wire bonding process. First ball 410 may also be referred to as a “free air ball.” For example, first ball 410 may be of a substantially spherical and/or substantially symmetrical shape formed as a result of melting a portion of the wire including first wire segment 108. Such melting may be the result of an electrical spark produced by wire enlarging mechanism 408 and/or the ionization of the air gap between first wire segment 108 and wire enlarging mechanism 408. Wire enlarging mechanism 408 may be, for example, an electronic flame-off (“EFO”) wand present within wire bonding machinery. In current configurations of wire bonding machinery, wire enlarging mechanism 408 may be held stationary at a height 412 above bonding surface 110 (e.g., stationary in a z-axis). In accordance with certain embodiments of the present disclosure, wire enlarging mechanism 408 may vary in height relative to a bonding surface in order to implement multiple ball bonds such that the multiple ball bonds may be spaced differently.

In some embodiments, first ball formation 400 may also include capillary 402. Capillary 402 may be an appropriate structure operable to direct first ball 410 such that first ball 410 may be bonded to bonding surface 110. For example, capillary 402 may include a chamber surrounding first wire segment 108, wherein the outer surface of the chamber tapers toward first wire segment 108 at the end of first wire segment 108 closest to bonding surface 110. Once first ball 410 comes into contact with bonding surface 110, capillary 402 may deform some or all of first ball 410 in order to facilitate bonding of first ball 410 to bonding surface 110.

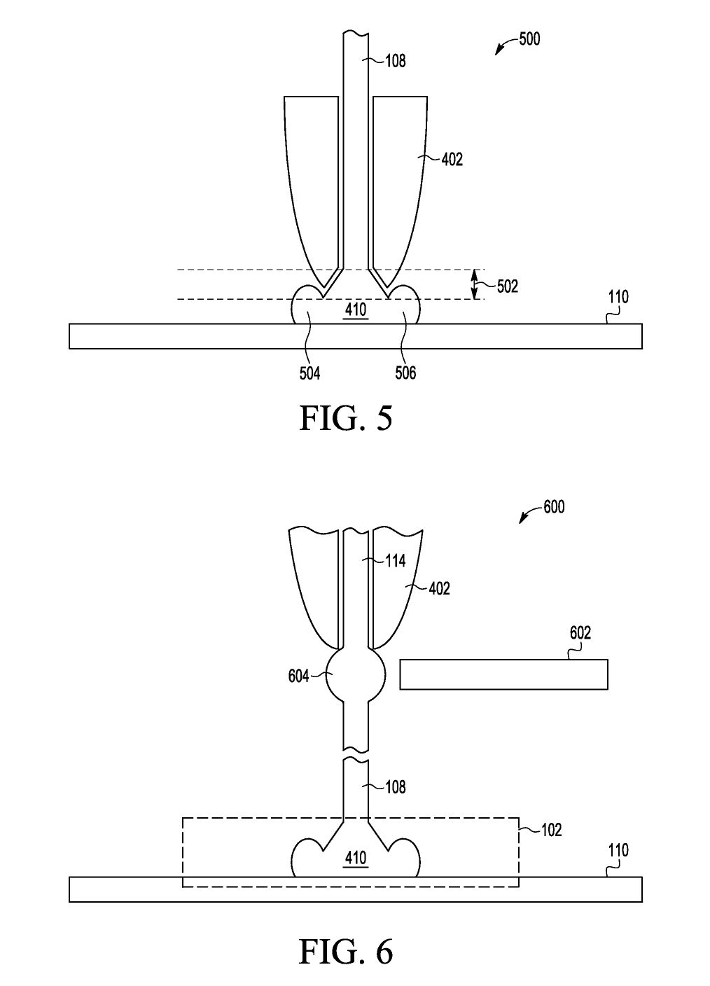

FIG. 5 illustrates a cross-section of an example deformation 500 of first ball 410 during formation of first ball bond 102, in accordance with certain embodiments of the present disclosure. As described in more detail above with reference to FIG. 4, capillary 402 may be operable to direct first ball 410 toward bonding surface 110 in order to facilitate bonding of first ball 410 to bonding surface 110. The geometry of the portion of capillary 402 proximal to first ball 410 (e.g., a chamfer region of capillary 402) may form a capillary chamfer imprint portion 502 of deformed first ball 410. Further, as a result of the impact between first ball 410 and bonding surface 110, first ball 410 may be deformed to have deformed portions 504, 506. Once appropriate contact has been made between first ball 410 and bonding surface 110, the bonding process may continue in order to form first ball bond 102.

FIG. 6 illustrates a cross-section of an example second ball formation 600, in accordance with certain embodiments of the present disclosure. Second ball formation 600 may include forming second ball 604 coupled to first ball bond 102 via first wire portion 108, as well as second wire portion 114 extending from second ball 604 toward capillary 402.

In some embodiments, second ball formation 600 may include forming second ball 604 from the wire including first and second wire segments 108, 114. Second ball 604 may be a segment of the wire enlarged to facilitate a wire bonding process. Second ball 604 may also be referred to as a “mid-span ball.” For example, second ball 604 may be of a substantially spherical and/or substantially symmetrical shape formed as a result of melting a portion of the wire including first and second wire segments 108, 114. Such melting may be the result of an electrical spark produced by wire enlarging mechanism 602 and/or the ionization of the air gap between first and second wire segments 108, 114 and wire enlarging mechanism 602. Wire enlarging mechanism 602 may be operable to vary in height relative to a bonding surface in order to accommodate the desired distance between first ball bond 102 and second ball 604. That is, the length of first wire segment 108 may be directly related to the distance between first ball bond 102 and second ball bond 104. Further, for any given semiconductor structure, the distance between first and second ball bonds 102, 104 may vary. Therefore, wire enlarging mechanism 602 may be operable to vary in height relative to bonding surface 110.

In some embodiments, wire enlarging mechanism 602 may be an electronic flame-off (“EFO”) wand present within wire bonding machinery. In some configurations, wire enlarging mechanism 602 and wire enlarging mechanism 408 may be the same mechanism. In the same or alternative configurations, wire enlarging mechanisms 408, 602 may be separate mechanisms. In some embodiments, capillary 402 may be operable to direct second ball 604 toward a bonding surface in order to facilitate bonding of first and second wire portions 108, 114 to that bonding surface (e.g., forming second ball bond 104 at second bonding surface 112).

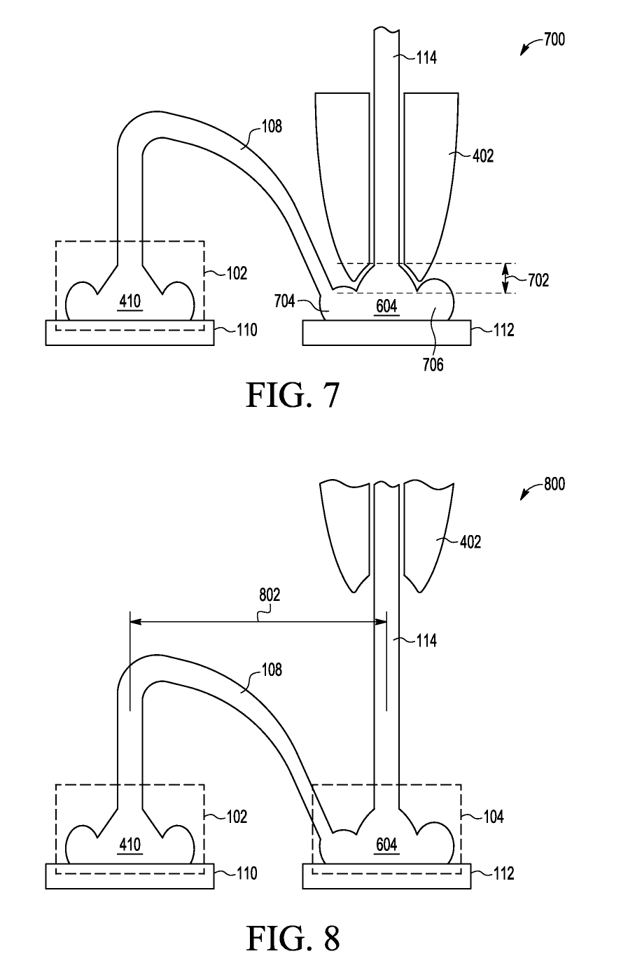

FIG. 7 illustrates a cross-section of an example deformation 700 of second ball 604 during formation of second ball bond 104, in accordance with certain embodiments of the present disclosure. As described in more detail above with reference to FIGS. 4-6, capillary 402 may be operable to direct second ball 604 toward bonding surface 112 in order to facilitate bonding of second ball 604 to bonding surface 112. The geometry of the portion of capillary 402 proximal to second ball 604 may form a capillary chamfer imprint portion 702 of deformed second ball 604. Further, as a result of the impact between second ball 604 and bonding surface 112, second ball 604 may be deformed to have deformed portions 704, 706. Once appropriate contact has been made between second ball 604 and bonding surface 112, the bonding process may continue in order to form second ball bond 104. The resulting ball bond may include a portion of first wire segment 108 coupled to second ball 604 below a portion of capillary chamfer imprint portion 702 (e.g., coupled to deformed portion 704) and above bonding surface 112.

FIG. 8 illustrates a cross-section of an example pre-formation 800, in accordance with certain embodiments of the present disclosure. Pre-formation 800 may include first ball bond 102 coupled to second ball bond 104 via first wire portion 108. Further, pre-formation 800 may include second wire portion 114 extending from second ball bond 104 and into a portion of capillary 402. As described in more detail above with reference to FIGS. 1-7, second wire portion 114 may be used to form one or more additional ball bonds and/or termination point 106.

In some embodiments, distance 802 may be associated with a distance between first and second ball bonds 102, 104. Distance 802 may vary depending on certain design configurations for a given semiconductor structure. That is, distance 802 may vary between or among different configurations of structure 100 as well as within the same configuration of structure 100. As described in more detail above with reference to FIGS. 4-7, wire enlarging mechanism 602 may vary in its position relative to a bonding surface in order to position second ball 406 along the wire in order to accommodate distance 802. After completing second wire bond 104, structure 100 may resemble the example structure depicted in FIG. 1.

By now it should be appreciated that there has been provided certain structures and methods for implementing a multiple ball bond semiconductor structure. Such systems and methods may allow for improved wire bonding performance among different semiconductor structures (e.g., by allowing a single wire bond path among more than two semiconductor structures and/or more than two portions of the same semiconductor structure). Further, such systems and methods may allow for improved efficiencies in the formation of semiconductor structures by allowing for the implementation of more cost-effective materials in the formation processes. For example, multiple ball bonding may allow for the use of aluminum in place of gold and/or gold alloys when bonding a die to a substrate.

Although the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, any number of ball bonds may be present between first ball bond 102 and termination point 106. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

Disclosed is a method for forming a semiconductor device (100). The method may include forming a first ball bond (102) on a first contact pad (110), forming a mid-span ball (604) in the first wire segment at a first distance from the ball bond; and after forming the mid-span ball, attaching the mid-span ball to a second contact pad (112) to form a second ball bond (104). The first ball bond may have a first wire segment (108) of a bonding wire extending from the ball bond. The method may also include detaching the bonding wire from the second ball bond.

In some embodiments, forming the mid-span ball may be performed while the first ball bond is attached to the first contact pad. In the same or alternative embodiments, after attaching the mid-span ball to the second contact pad, a second wire segment (114) of the bonding wire extends from the second ball bond. The method may then also include forming a second mid-span ball in the second wire segment at a second distance from the second ball bond, and attaching the second mid-span ball to a third contact pad. The method may also then include forming a stitch bond (204) with the second wire segment to a third contact pad.

In some embodiments, the first contact pad may be on a semiconductor die and the second contact pad may be on a package substrate. In the same or alternative embodiments, the first contact pad may be on a first semiconductor die and the second contact pad may be on a second semiconductor die. In the same or alternative embodiments, the first contact pad may be on a first semiconductor die and the second contact pad may be on the same semiconductor die.

In some embodiments, the forming the mid-span ball may include using an electronic-flame-off (EFO) (602) wand to form the mid-span ball. In such embodiments, forming the first ball bond may include forming a free air ball at an end of the bonding wire using the EFO wand, and attaching the free air ball to the first contact pad to form the first ball bond. Further, in such embodiments the EFO may be used at a first height as measured from the first contact pad for forming the free air ball and a second height, different from the first height, as measured from the first contact pad to form the mid-span ball.

In some embodiments, the bonding wire may include copper and the second contact pad may include aluminum. In the same or alternative embodiments, the mid-span ball may have a diameter greater than a diameter of the first wire segment. In the same or alternative embodiments, the wire may comprise one of copper, gold, silver, aluminum or other suitable bonding wire material.

Also disclosed is at least one additional method for forming a semiconductor device. Such a method may include forming a free air ball (410) at an end of a bonding wire using an EFO wand, attaching the free air ball to a first contact pad to form a first ball bond (102), wherein a first wire segment (108) of the bonding wire may remain extending from the first ball bond after the attaching, forming a mid-span ball (604) in the first wire segment at a first distance from the ball bond using the EFO wand, and attaching the mid-span ball to a second contact pad (112) to form a second ball bond (104).

In some embodiments, the EFO may be used at a first height as measured from the first contact pad for forming the free air ball and a second height, different from the first height, as measured from the first contact pad to form the mid-span ball. In the same or alternative embodiments, the method may also include detaching the bonding wire from the second ball bond.

In some embodiments, after attaching the mid-span ball to the second contact pad, a second wire segment of the bonding wire may extend from the second ball bond, and a stitch bond may be formed with the second wire segment to a third contact pad.

A semiconductor device (100) is also disclosed. The semiconductor device may include a first contact pad (112) on one of a semiconductor die or a semiconductor package substrate, a first ball bond (104) having a bottom surface in contact with the first contact and having a capillary chamfer imprint, and a wire segment (108) extending from the first ball bond, wherein the wire segment extends from a location of the first ball bond that is located below the capillary chamfer imprint and above the bottom surface.

In some embodiments, the semiconductor device may also include a second contact pad (110) on one of a second semiconductor die or a second semiconductor package substrate, and a second ball bond (102) on the second contact pad, wherein the wire segment extends from a top surface of the second ball bond.

In the same or alternative embodiments, the first ball bond may be substantially symmetrical about an axis which extends perpendicularly from the first contact pad.

What is claimed is:

1. A method for forming a semiconductor device, the method comprising:
forming a first ball bond on a first contact pad, the first ball bond having a first wire segment of a bonding wire extending from the ball bond;
forming a mid-span ball in the first wire segment at a first distance from the ball bond; and
after the forming the mid-span ball, attaching the mid-span ball to a second contact pad to form a second ball bond.

2. The method of claim 1, wherein the forming the mid-span ball is performed while the first ball bond is attached to the first contact pad.

3. The method of claim 1, further comprising;
detaching the bonding wire from the second ball bond;

4. The method of claim 1, wherein after the attaching the mid-span ball to the second contact pad, a second wire segment of the bonding wire extends from the second ball bond.

5. The method of claim 4, further comprising:
forming a second mid-span ball in the second wire segment at a second distance from the second ball bond; and
attaching the second mid-span ball to a third contact pad.

6. The method of claim 4, further comprising:
forming a stitch bond with the second wire segment to a third contact pad.

7. The method of claim 1, wherein the first contact pad is on a semiconductor die and the second contact pad is on a package substrate.

8. The method of claim 1, wherein the first contact pad is on a first semiconductor die and the second contact pad is on a second semiconductor die.

9. The method of claim 1, wherein the forming the mid-span ball comprises:
using an electronic-flame-off (EFO) wand to form the mid-span ball.

10. The method of claim 9, wherein the forming the first ball bond comprises:
forming a free air ball at an end of the bonding wire using the EFO wand; and
attaching the free air ball to the first contact pad to form the first ball bond.

11. The method of claim 10, wherein the EFO is used at a first height as measured from the first contact pad for forming the free air ball and a second height, different from the first height, as measured from the first contact pad to form the mid-span ball.

12. The method of claim 1, wherein the bonding wire comprises copper and the second contact pad comprises aluminum.

13. The method of claim 1, wherein the mid-span ball has a diameter greater than a diameter of the first wire segment.

14. A method for forming a semiconductor device, the method comprising:
forming a free air ball at an end of a bonding wire using an EFO wand;
attaching the free air ball to a first contact pad to form a first ball bond, wherein a first wire segment of the bonding wire remains extending from the first ball band after the attaching;
forming a mid-span ball in the first wire segment at a first distance from the ball bond using the EFO wand; and
attaching the mid-span ball to a second contact pad to form a second ball bond.

15. The method of claim 14, wherein the EFO is used at a first height as measured from the first contact pad for forming the free air ball and a second height, different from the first height, as measured from the first contact pad to form the mid-span ball.

16. The method of claim 14, further comprising;
detaching the bonding wire from the second ball bond;

17. The method of claim 14, wherein after the attaching the mid-span ball to the second contact pad, a second wire segment of the bonding wire extends from the second ball bond, the method further comprising forming a stitch bond with the second wire segment to a third contact pad.

18. A semiconductor device, comprising:
a first contact pad on one of a semiconductor die or a semiconductor package substrate;
a first ball bond having a bottom surface in contact with the first contact pad and having a capillary chamfer imprint; and
a wire segment extending from the first ball bond, wherein a portion of the wire segment extends from a location of the first ball bond that is located below the capillary chamfer imprint and above the bottom surface.

19. The semiconductor device of claim 18, further comprising:
a second contact pad on one of a second semiconductor die or a second semiconductor package substrate; and
a second ball bond on the second contact pad, wherein the wire segment extends from a top surface of the second ball bond.

20. The semiconductor device of claim 18, wherein the first ball bond is substantially symmetrical about an axis which extends perpendicularly from the first contact pad.
